(19) United States
(12) Patent Application Publication
(10) Pub. No.: US 2025/0370046 A1
(43) Pub. Date: Dec. 4, 2025

(54) DEGRADATION DETERMINATION DEVICE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Takahiro OKAMOTO, Osaka (JP); Hiroki SHIMODA, Osaka (JP); Taiji YANAGIDA, Osaka (JP); Manabu HASHIKURA, Osaka (JP); Koki UCHIDA, Mie (JP); Takafumi KAWAKAMI, Mie (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 18/881,518

(22) PCT Filed: Apr. 10, 2023
(86) PCT No.: PCT/JP2023/014615

§ 371 Date: Jan. 6, 2025

(30) Foreign Application Priority Data
Jul. 12, 2022 (WO) PCT/JP2022/027379

(51) Int. Cl. G01R 31/327; G01R 31/74

(52) U.S. Cl. CPC G01R 31/3278; G01R 31/74

(57) ABSTRACT

A degradation determination device determines whether each of a first opening/closing device and a fuse provided on a power path is in a degraded state. The power path has a positive electrode-side power line and a negative electrode-side power line. The first opening/closing device and the fuse are provided on the negative electrode-side power line. The degradation determination device is provided with a first potential detection unit that detects a first potential at one end of the first opening/closing device and a second potential at the opposite end thereof, a second potential detection unit that detects a first potential at one end of the fuse and a second potential at the opposite end thereof, and a control unit that determines whether each of the first opening/closing device and the fuse is in a degraded state, based on a potential difference between the first and second potentials.

### TECHNICAL FIELD

The present disclosure relates to a degradation determination device.

### BACKGROUND ART

Patent Document 1 discloses a technology for optimizing the degree of degradation of a relay by adjusting the precharge time when precharging an inverter with a precharge circuit.

### CITATION LIST

### Patent Documents

Patent Document 1: JP 2020-78196A

### SUMMARY OF INVENTION

### Technical Problem

As a method of grasping whether an element satisfies required performance, a known technique involves determining whether an element satisfies required performance by setting an upper limit value for the frequency of current application to the element in advance and comparing the frequency of current application with the upper limit value. However, this technique does not take account of the magnitude of the current flowing through the element or the end-to-end potential difference of the element. Thus, with this technique, a situation can arise in which it is not possible to properly grasp whether the element satisfies the required performance in a manner based on actual usage of the element.

The present disclosure has been made on the basis of the above-described circumstances, and an object thereof is to provide a degradation determination device that is able to more properly determine degradation of an element.

### Solution to Problem

The degradation determination device of the present disclosure is:
A degradation determination device for determining whether an element provided on a power path, which is a path for transmitting power from a power supply unit to a load, is in a degraded state,
the power path having:
   a positive electrode-side power line connected to a positive electrode-side terminal of the power supply unit; and
   a negative electrode-side power line connected to a negative electrode-side terminal of the power supply unit,
the element being provided on the negative electrode-side power line, and
the degradation determination device including:
   a potential detection unit configured to detect a first potential at one end of the element and a second potential at an opposite end of the element; and
   a control unit configured to determine whether the element is in a degraded state, based on a potential difference between the first potential and the second potential.

### Advantageous Effects of Invention

According to the present disclosure, degradation of an element can be more properly determined.

### BRIEF DESCRIPTION OF DRAWINGS

FIG. 1 is a circuit diagram illustrating a vehicle power supply system provided with a degradation determination device of a first embodiment.

FIG. 2 is a flowchart illustrating an example of control by a control unit in the degradation determination device of the first embodiment.

### DESCRIPTION OF EMBODIMENTS

### Description of Embodiments of Disclosure

Initially, modes of the present disclosure will be enumerated and described.

(1) A degradation determination device for determining whether an element provided on a power path, which is a path for transmitting power from a power supply unit to a load, is in a degraded state,
the power path having:
   a positive electrode-side power line connected to a positive electrode-side terminal of the power supply unit; and
   a negative electrode-side power line connected to a negative electrode-side terminal of the power supply unit,
the element being provided on the negative electrode-side power line, and
the degradation determination device including:
   a potential detection unit configured to detect a first potential at one end of the element and a second potential at an opposite end of the element; and
   a control unit configured to determine whether the element is in a degraded state, based on a potential difference between the first potential and the second potential.

In the degradation determination device of (1), the element is provided on the negative electrode-side power line, and thus, even if the voltage applied to the element varies at a predetermined variation rate, the extent of the variation is less than the extent to which the voltage varies at the predetermined variation rate on the positive electrode-side power line. Thus, the extent to which the calculated resistance value of the element provided on the negative electrode-side power line varies is easily suppressed.

(2) In the degradation determination device of (1),
the element may be a first element,
a second element different from the first element may be provided on the positive electrode-side power line,
the degradation determination device may further include a temperature detection unit configured to detect a temperature of each of the first element and the second element, and
the control unit may determine whether the second element is in a degraded state, based on the potential difference and a temperature value detected by the temperature detection unit.

The end-to-end potential difference of the second element varies to a greater extent than the first element, and there is concern that the resistance value will become more volatile. Thus, the degradation determination device of (2) is able to determine in a simple manner whether the second element is in a degraded state, using the temperature detection unit.

(3) In the degradation determination device of (2), the element may be at least one of a relay and a fuse.

When the electrical characteristics of the relay or fuse change due to degradation, there is concern that it will no longer be possible to cut off the power path as per the specifications, but as a result of the degradation determination device of (3) determining whether the relay and fuse are in a degraded state, it becomes easier to take action before such concerns arise.

(4) In the degradation determination device of (3),
the first element and the second element may each be the relay, and
a precharge circuit may be connected to the power path so as to be in parallel with the first element.

In the degradation determination device of (4), the relay to which the precharge circuit is connected in parallel is prone to inrush current and is thus susceptible to degradation. Thus, by measuring the resistance value of the relay to which the precharge circuit is connected in parallel, it is possible to grasp the degree of degradation of the relay which is susceptible to degradation.

In the degradation determination device of any one of (1) to (4), the control unit may perform anomaly response processing when it is determined that the element is in a degraded state.

With the degradation determination device of (5), performing anomaly response processing facilitates taking action that is based on the element having degraded.

### DETAILED DESCRIPTION OF EMBODIMENTS OF DISCLOSURE

Specific examples of the present disclosure will be described below with reference to the drawings. Note that the present invention is not limited to these illustrative examples and is indicated by the claims, and all changes that come within the meaning and range of equivalency of the claims are intended to be embraced therein.

### First Embodiment

### Configuration of Degradation Determination Device

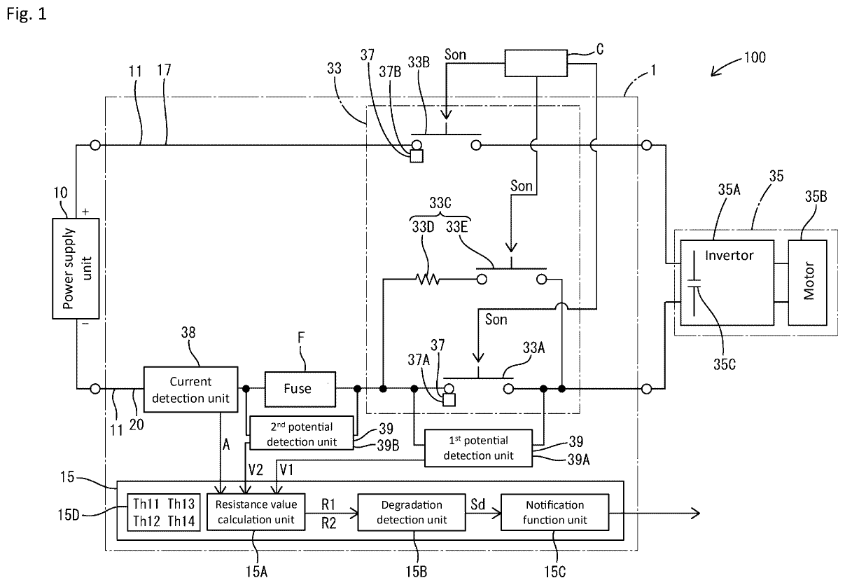

A vehicle power supply system 100 shown in FIG. 1 is a power supply system that is installed in a vehicle, and has a power supply unit 10, a power path 11, a system main relay 33, and a degradation determination device 1. The degradation determination device 1 has a temperature detection unit 37, a current detection unit 38, a potential detection unit 39, and a control unit 15. The potential detection unit 39 has a first potential detection unit 39A and a second potential detection unit 39B. The vehicle power supply system 100 is configured to supply power from the power supply unit 10 to a load 35 via the power path 11, which is a path through which power is transmitted between the power supply unit 10 and the load 35.

The power supply unit 10 is a battery that can supply power to the load 35. The power supply unit 10 is, for example, a battery pack constituted by combining a plurality of single batteries such as lead batteries, lithium-ion batteries, or nickel-metal hydride batteries in series.

The power path 11 is provided with a positive electrode-side power line 17 and a negative electrode-side power line 20. The positive electrode-side power line 17 is electrically connected to a positive electrode-side terminal of the power supply unit 10. An output voltage of the power supply unit 10 is applied to the positive electrode-side power line 17. The negative electrode-side power line 20 is electrically connected to a negative electrode-side terminal of the power supply unit 10. The negative electrode-side power line 20 has a lower potential than the positive electrode-side power line 17. The negative electrode-side terminal of the power supply unit 10 is, for example, electrically connected to the metal body of the vehicle, and is assumed to have the same potential as the metal body of the vehicle.

The output voltage of the power supply unit 10 corresponds to the potential difference between the positive electrode-side terminal and the negative electrode-side terminal. The power path 11 is a path for transmitting power from the power supply unit 10 to the load 35. A fuse F serving as a first element is provided on the negative electrode-side power line 20. The fuse F cuts off application of current to the negative electrode-side power line 20 when an excessive current flows through the negative electrode-side power line 20. A thermal fuse, for example, is used for the fuse F.

In the present disclosure, “electrically connected” is desirably a configuration in which the connection targets are connected in a state where they are in continuity with each other (state where current flows therebetween) such that the potentials of the connection targets are equal. The present disclosure is, however, not limited to this configuration. For example, “electrically connected” may be a configuration in which the connection targets have an electrical component interposed therebetween and are connected in a state where they can be in continuity with each other.

The load 35 is electrically connected to the positive electrode-side power line 17 and the negative electrode-side power line 20. The load 35 is an in-vehicle electronic component, and products such as an electric component, an ECU, and a component targeted at ADAS, for example, are applicable. In the first embodiment, the load 35 includes an inverter 35A and a motor 35B, and the inverter 35A has a capacitor 35C. The capacitor 35C smooths a voltage that is based on the power supply unit 10 and supplies the smoothed voltage to the inverter 35A. The inverter 35A is electrically connected to the power path 11. The inverter 35A generates an AC voltage (e.g., three-phase alternating current) from a DC voltage that is based on the voltage supplied from the power supply unit 10 and supplies the AC voltage to the motor 35B. The motor 35B is, for example, the motor of a main engine system. The motor 35B rotates based on the power supplied from the power supply unit 10 and applies a rotational force to the wheels of the vehicle. Current output by the positive electrode-side terminal of the power supply unit 10 flows in order of the positive electrode-side power line 17, the load 35, the negative electrode-side power line 20, and the negative electrode-side terminal of the power supply unit 10.

The system main relay 33 is interposed in the positive electrode-side power line 17 and the negative electrode-side power line 20 between the power supply unit 10 and the load 35. The system main relay 33 has a first opening/closing device 33A which is a relay and serves as a first element, a second opening/closing device 33B which is a relay and serves as a second element, and a parallel opening/closing path 33C. That is, the first element includes the first opening/closing device 33A and the fuse F. The second opening/closing device 33B is a different element from the first opening/closing device 33A. The first opening/closing device 33A and the second opening/closing device 33B are, for example, mechanical relay switches each internally having a contact that physically switches between a contact state and a separated state. The parallel opening/closing path 33C is a so-called precharge circuit. The parallel opening/closing path 33C has a resistor 33D and a third opening/closing device 33E which is a relay connected in series to the resistor 33D. The third opening/closing device 33E is a mechanical relay switch having a similar configuration to the first opening/closing device 33A and the second opening/closing device 33B. The third opening/closing device 33E is a so-called precharge relay.

The first opening/closing device 33A is provided on the negative electrode-side power line 20 on the opposite side to the power supply unit 10 with the fuse F therebetween. The second opening/closing device 33B is provided on the positive electrode-side power line 17. The resistor 33D and the third opening/closing device 33E of the parallel opening/closing path 33C are electrically connected to the negative electrode-side power line 20 so as to be in parallel with the first opening/closing device 33A. The first opening/closing device 33A, the second opening/closing device 33B, and the third opening/closing device 33E are controlled to switch between an ON state and an OFF state by a predetermined control device C (hereinafter, also referred to simply as control device C). The first opening/closing device 33A, the second opening/closing device 33B, and the third opening/closing device 33E switch the power path 11 between a continuity state and a cut-off state, by switching between the ON state and the OFF state.

The temperature detection unit 37 is individually provided for the first opening/closing device 33A and the second opening/closing device 33B, and detects the temperature of the respective contacts within the first opening/closing device 33A and the second opening/closing device 33B when the corresponding first opening/closing device 33A and second opening/closing device 33B are in the ON state. The temperature detection unit 37 has a first temperature detection unit 37A provided for the first opening/closing device 33A and a second temperature detection unit 37B provided for the second opening/closing device 33B. The first temperature detection unit 37A and the second temperature detection unit 37B each output a temperature value indicating the detected temperature. Based on the respective temperature values from the first temperature detection unit 37A and the second temperature detection unit 37B, the control unit 15 specifies the temperatures of the respective contacts when the first opening/closing device 33A and the second opening/closing device 33B are in the ON state.

The current detection unit 38 is interposed in the negative electrode-side power line 20 closer to the power supply unit 10 side than is the first opening/closing device 33A. The current detection unit 38 has, for example, a resistor and a differential amplifier, and is configured to output a value indicating the current flowing through the negative electrode-side power line 20 (specifically, analog voltage that depends on the value of current flowing through the negative electrode-side power line 20) as a current value A. That is, the current detection unit 38 detects the state of current flowing through the power path 11 as the current value A.

The first potential detection unit 39A is, for example, constituted as a potential detection circuit. The first potential detection unit 39A is configured to detect a first potential of the terminal on the power supply unit 10 side, which is the terminal at one end, of the first opening/closing device 33A, and a second potential of the terminal on the load 35 side, which is the terminal as the opposite end, of the first opening/closing device 33A, and output a potential difference V1 between the first potential and the second potential. In other words, the first potential detection unit 39A detects the potential difference between the terminals on the power supply unit 10 side and the load 35 side of the first opening/closing device 33A (terminals on both sides of the first opening/closing device 33A, namely, the side on which power is supplied to the first opening/closing device 33A and the side on which power is output) as the potential difference V1.

The second potential detection unit 39B is, for example, constituted as a potential detection circuit similar to the first potential detection unit 39A. The second potential detection unit 39B is configured to detect a first voltage of the terminal on the power supply unit 10 side, which is the terminal at one end, of the fuse F, and a second potential of the terminal on the load 35 side, which is the terminal at the opposite end, of the fuse F, and output a potential difference V2 between the first potential and the second potential. In other words, the second potential detection unit 39B detects the potential difference between the terminals on the power supply unit 10 side and the load 35 side of the fuse F (terminals on both sides of the fuse F, namely, the side on which power is supplied to the fuse F and the side on which power is output) as the potential difference V2.

The potential differences V1 and V2 between the first and second potentials may be values calculated by an analog circuit (e.g., differential amplifier circuit), or may be values calculated by a digital circuit after AD conversion of the first and second potentials.

The control unit 15 is, for example, constituted as a microcomputer, and is equipped with a CPU, a ROM, a RAM, and a storage unit 15D constituted by a non-volatile memory or the like. The control unit 15 is provided with a resistance value calculation unit 15A, a degradation detection unit 15B, and a notification function unit 15C.

The resistance value calculation unit 15A is configured to receive input of the current value A, the potential difference V1, and the potential difference V2 from the current detection unit 38, the first potential detection unit 39A, and the second potential detection unit 39B, respectively. The resistance value calculation unit 15A calculates a resistance value R1 of the first opening/closing device 33A and a resistance value R2 of the fuse F based on these values (current value A, potential differences V1, V2). For example, the resistance value R1 of the first opening/closing device 33A is derived by dividing the potential difference V1 by the current value A. The resistance value R2 of the fuse F is derived by dividing the potential difference V2 by the current value A. That is, the control unit 15 calculates the respective resistance values R1 and R2 of the first opening/closing device 33A and the fuse F, which serve as the first element, based on the potential differences V1 and V2 between the first and second potentials. For example, the first opening/closing device 33A and the fuse F are characterized by the resistance values R1 and R2 gradually increasing when current is repeatedly applied and stopped. That is, the control unit 15 grasps the respective degrees of degradation of the first opening/closing device 33A and the fuse F by calculating the resistance values R1 and R2.

The degradation detection unit 15B is configured to execute degradation determination processing. The degradation determination processing involves comparing the resistance value R1 calculated in the resistance value calculation unit 15A with a resistance threshold value Th11 stored in the storage unit 15D of the control unit 15, and comparing the resistance value R2 calculated in the resistance value calculation unit 15A with a resistance threshold value Th12 stored in the storage unit 15D of the control unit 15.

For example, the degradation detection unit 15B is configured to output a degradation signal Sd when it is determined that the resistance value R1 exceeds the resistance threshold value Th11 or the resistance value R2 exceeds the resistance threshold value Th12. The degradation signal Sd is output when either the first opening/closing device 33A or the fuse F is in a degraded state. That is, the control unit 15 determines that the first opening/closing device 33A is in a degraded state when the resistance value R1 exceeds the resistance threshold value Th11, and determines that the fuse F is in a degraded state when the resistance value R2 exceeds the resistance threshold value Th12. In the degradation determination processing, the degradation detection unit 15B does not output the degradation signal Sd when it is determined that the magnitude of the resistance value R1 is less than or equal to the resistance threshold value Th11 and the magnitude of the resistance value R2 is less than or equal to the resistance threshold value Th12. In this case, the control unit 15 determines that the first opening/closing device 33A and the fuse F are not in a degraded state. In this way, the control unit 15 determines whether each of the first opening/closing device 33A and the fuse F are in a degraded state.

The notification function unit 15C is, for example, constituted by a communication device, and is configured to perform anomaly response processing for giving notifications by transmitting information to an external device not shown such as a BMS (battery management system), based on input of the degradation signal Sd from the degradation detection unit 15B. That is, the control unit 15 performs anomaly response processing, either when it is determined that the resistance value R1 exceeds the resistance threshold value Th11 and the first opening/closing device 33A is in a degraded state, or when it is determined that the resistance value R2 exceeds the resistance threshold value Th12 and the fuse F is in a degraded state.

### Regarding Control by Control Unit

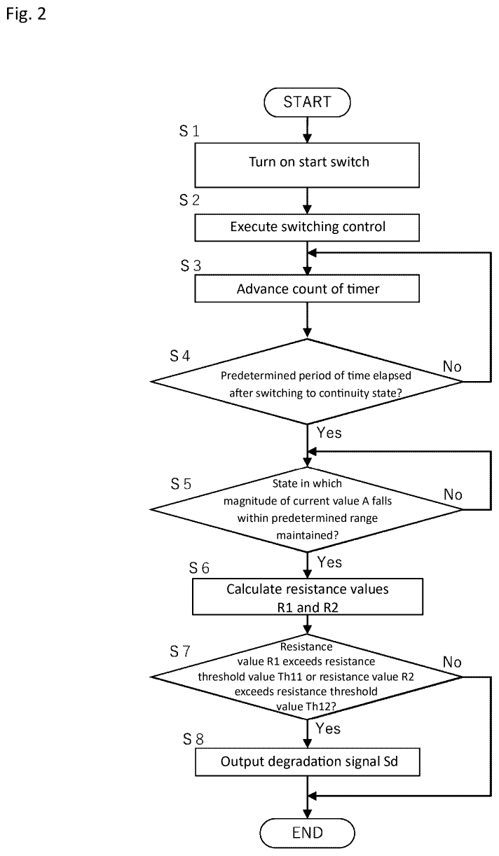

Next, an example of control executed by the control unit 15 will be described with reference to FIG. 2 and the like. For example, when the start switch is OFF in a vehicle equipped with the vehicle power supply system 100, the first opening/closing device 33A and the second opening/closing device 33B of the system main relay 33 and the third opening/closing device 33E of the parallel opening/closing path 33C are maintained in the OFF state. At this time, the power path 11 is in a cut-off state in which supply of power from the power supply unit 10 to the load 35 is cut off.

From this state, first, step S1 is executed and the start switch is switched from OFF to ON. Next, when the processing transitions to step S2, an ON signal Son (see FIG. 1) is output by the control device C, and switching control is executed in which the first opening/closing device 33A, the second opening/closing device 33B, and the third opening/closing device 33E are switched from the OFF state to the ON state based on the ON signal Son. Specifically, the switching control involves switching the second opening/closing device 33B and the third opening/closing device 33E to the ON state while maintaining the first opening/closing device 33A in the OFF state to start application of current to the power path 11, and thereafter switching the first opening/closing device 33A to the ON state while maintaining the second opening/closing device 33B and the third opening/closing device 33E in the ON state. That is, the first opening/closing device 33A switches from the OFF state to the ON state after the second opening/closing device 33B.

Note that the power path 11 starts applying current when the second opening/closing device 33B and the third opening/closing device 33E are turned ON. The resistor 33D is connected in series to the third opening/closing device 33E, and thus current starts flowing slowly through the power path 11 so as to gradually increase.

Furthermore, when the first opening/closing device 33A is turned ON, the power path 11 enters a conductive state in which supply of power from the power supply unit 10 to the load 35 is permitted. When the first opening/closing device 33A switches to the ON state, an inrush current immediately flows through the first opening/closing device 33A. At this time, current rise occurs in which the current value A flowing through the power path 11 rises rapidly. In this way, start of current application or current rise on the power path 11 occurs due to the switching control being executed. The inrush current continues to flow for a predetermined short period of time after the first opening/closing device 33A switches to the ON state, and, after the predetermined short period of time has elapsed, the current flowing through the first opening/closing device 33A settles so as to stay within a predetermined range smaller than the magnitude of the inrush current. In this way, the first opening/closing device 33A enters the ON state and current flows through the power path 11.

The processing then transitions to step S3. The control unit 15 is equipped with a timer function and starts measurement of a predetermined short period of time from when the current value A reaches a predetermined magnitude from 0. The predetermined short period of time is the time that it takes for the current flowing through the first opening/closing device 33A to settle within the predetermined range smaller than the magnitude of the inrush current.

Then, when the processing transitions to step S4, the control unit 15 determines whether the predetermined short period of time has elapsed from when the current value A of the power path 11 reached the predetermined magnitude from 0. Step S4 involves processing for waiting for the current flowing through the first opening/closing device 33A to settle within the predetermined range smaller than the magnitude of the inrush current, by waiting for the predetermined short period of time to elapse. For example, when the control unit 15, in step S4, determines that the predetermined short period of time has not elapsed from when the current value A of the power path 11 reached the predetermined magnitude from 0 (No in step S4), the processing again transitions to step S3. When the processing again transitions to step S3, the count of the timer with which the control unit 15 is equipped advances, and, thereafter, the processing of step S4 is repeated again.

Then, when the control unit 15, in step S4, determines that the predetermined short period of time has elapsed from when the current value A of the power path 11 reached the predetermined magnitude from 0 (Yes in step S4), the processing transitions to step S5. When the processing transitions to step S5, the control unit 15 determines whether the state in which the magnitude of the current value A falls within the predetermined range has been maintained. For example, the control unit 15 is configured to compare the current value A input from the current detection unit 38 with a current threshold value Th13 stored in the storage unit 15D of the control unit 15 and an upper limit current threshold value Th14 that is larger than the current threshold value Th13. For example, the control unit 15 is configured to use the timer function with which it is equipped to determine whether the state where the magnitude of the current value A is greater than or equal to the current threshold value Th13 and less than the upper current threshold Th14 has continued for a predetermined period of time (i.e., variability of current flowing through the power path 11 has settled). When, in step S5, the control unit 15 determines that the state in which the magnitude of the current value A is greater than or equal to the current threshold value Th13 and less than the upper limit current threshold value Th14 has not continued for the predetermined period of time (No in step S5), the processing of step S5 is repeated.

When, in step S5, the control unit 15 determines that the state in which the magnitude of the current value A is greater than or equal to the current threshold value Th13 and less than the upper limit current threshold Th14 has continued for the predetermined period of time (Yes in step S5), the processing transitions to step S6. When the processing transitions to step S6, the control unit 15 calculates the resistance values R1 and R2 based on the current value A and the potential differences V1 and V2 respectively input from the current detection unit 38, the first potential detection unit 39A, and the second potential detection unit 39B, using the resistance value calculation unit 15A. The processing then transitions to step S7.

When the processing transitions to step S7, the control unit 15 executes degradation determination processing for comparing the resistance value R1 with the resistance threshold value Th11 and comparing the resistance value R2 with the resistance threshold value Th12, using the degradation detection unit 15B. The control unit 15 executes the degradation determination processing for comparing the resistance values R1 and R2 at the time that the switching control by the control device C was executed with the resistance threshold values Th11 and Th12. For example, when, in the degradation determination processing, it is determined that the magnitude of the resistance value R1 is greater than or equal to the resistance threshold value Th11 or the magnitude of the resistance value R2 is greater than or equal to the resistance threshold value Th12 (Yes in step S7), the processing transitions to step S8 and the degradation signal Sd is output by the degradation detection unit 15B.

On the other hand, when, in the degradation determination processing, it is determined that the magnitude of the resistance value R1 is less than the resistance threshold value Th11 and the magnitude of the resistance value R2 is less than the resistance threshold value Th12 (No in step S7), the processing shown in FIG. 2 is ended without outputting the degradation signal Sd. In this way, the control unit 15 calculates the resistance value R1 of the first opening/closing device 33A, utilizing the potential difference V1 between the first potential at one end of the first opening/closing device 33A and the second potential at the opposite end of the first opening/closing device 33A. The control unit 15 then compares the resistance value R1 with the resistance threshold value Th11 to determine whether the first opening/closing device 33A is in a degraded state. The control unit 15 then calculates the resistance value R2 of the fuse F, utilizing the potential difference V2 between the first potential at one end of the fuse F and the second potential at the opposite end of the fuse F. The control unit 15 then compares the resistance value R2 with the resistance threshold value Th12 to determine whether the fuse F is in a degraded state.

Next, when the degradation signal Sd is input to the notification function unit 15C, the notification function unit 15C transmits information to an external device (not shown). That is, the notification function unit 15C of the control unit 15 performs anomaly response processing for externally notifying either that the resistance value R1 exceeds the resistance threshold value Th11 and the first opening/closing device 33A is in a degraded state, or that the resistance value R2 exceeds the resistance threshold value Th12 and the fuse F is in a degraded state. In this way, the processing shown in FIG. 2 ends.

For example, the control unit 15, in parallel with the processing shown in FIG. 2, performs processing for comparing the temperature value from the first temperature detection unit 37A with the temperature value from the second temperature detection unit 37B. As a result of this processing, the control unit 15 compares the temperature of the first opening/closing device 33A with the temperature of the second opening/closing device 33B. For example, the control unit 15 may be configured to estimate that the degree of degradation of the second opening/closing device 33B is greater than the degree of degradation of the first opening/closing device 33A, when it is determined that the temperature value from the second temperature detection unit 37B is greater than the temperature value from the first temperature detection unit 37A (i.e., temperature of second opening/closing device 33B is greater than temperature of first opening/closing device 33A).

Also, the control unit 15 may be configured to calculate the temperature difference between the first opening/closing device 33A and the second opening/closing device 33B, using the temperature value from the second temperature detection unit 37B and the temperature value from the first temperature detection unit 37A. Furthermore, the control unit 15 may be configured to execute temperature correction utilizing the temperature difference with respect to the calculated resistance value R1 of the first opening/closing device 33A and calculate the resistance value of the second opening/closing device 33B. That is, the control unit 15 determines whether the second opening/closing device 33B (second element) is in a degraded state, based on the resistance value R1 calculated based on the potential difference V1 and the temperature value detected by the temperature detection unit 37.

Next, the effects of the present configuration will be illustrated.

The degradation determination device 1 determines whether the first opening/closing device 33A and the fuse F (element) provided on the power path 11, which is a path for transmitting power from the power supply unit 10 to the load 35, are in a degraded state. The power path 11 has the positive electrode-side power line 17 connected to the positive electrode-side terminal of the power supply unit 10 and the negative electrode-side power line 20 connected to the negative electrode-side terminal of the power supply unit 10. The first opening/closing device 33A and the fuse F (element) are provided on the negative electrode-side power line 20. The degradation determination device 1 is provided with the first potential detection unit 39A, the second potential detection unit 39B, and the control unit 15. The first potential detection unit 39A detects the first potential at one end of the first opening/closing device 33A and the second potential at the opposite end of the first opening/closing device 33A. The second potential detection unit 39B detects the first potential at one end of the fuse F and the second potential at the opposite end of the fuse F. The control unit 15 determines whether each of the first opening/closing device 33A and the fuse F is in a degraded state based on the potential differences V1 and V2 between the first and second potentials.

In the degradation determination device 1, the first opening/closing device 33A and the fuse F are provided on the negative electrode-side power line 20. Thus, even if the voltage applied to the first opening/closing device 33A and the fuse F varies at a predetermined variation rate, the extent of the variation is less than the extent to which the voltage varies at the predetermined variation rate on the positive electrode-side power line 17. Thus, the extent of variation in the calculated resistance values R1 and R2 of the first opening/closing device 33A and the fuse F provided on the negative electrode-side power line 20 vary is easily suppressed.

The first opening/closing device 33A and the fuse F serve as the first element, and the second opening/closing device 33B (second element) which differs from the first opening/closing device 33A and the fuse F is provided on the positive electrode-side power line 17. Furthermore, the degradation determination device 1 is provided with the temperature detection unit 37 that detects the temperature of each of the first opening/closing device 33A and the second opening/closing device 33B. The control unit 15 determines whether the second opening/closing device 33B is in a degraded state, based on the potential difference V1 and the temperature value detected by the temperature detection unit 37.

The end-to-end potential difference of the second opening/closing device 33B varies to a greater extent than the first opening/closing device 33A, and there is concern that the resistance value of the second opening/closing device 33B will become more volatile. Thus, the degradation determination device 1 is able to determine in a simple manner whether the second opening/closing device 33B is in a degraded state, using the temperature detection unit 37.

The element is the first opening/closing device 33A and the fuse F.

When the electrical characteristics of the first opening/closing device 33A and the fuse F change due to degradation, there is concern that it will no longer be possible to cut off the power path 11 as per the specifications. However, as a result of the degradation determination device 1 determining whether each of the first opening/closing device 33A and the fuse F are in a degraded state, it becomes easier to take action before such concerns arise.

The first element is the first opening/closing device 33A which is a relay, and the second element is the second opening/closing device 33B which is a relay. On the power path 11, the parallel opening/closing path 33C (precharge circuit) is connected to the first opening/closing device 33A (first element) so as to be in parallel therewith.

In the degradation determination device 1, the first opening/closing device 33A to which the parallel opening/closing path 33C is connected in parallel is prone to inrush current and is thus susceptible to degradation. Thus, by measuring the resistance value R1 of the first opening/closing device 33A to which the parallel opening/closing path 33C is connected in parallel, it is possible to grasp the degree of degradation of the first opening/closing device 33A which is susceptible to degradation.

The control unit 15 performs anomaly response processing, either when it is determined that the resistance value R1 of the first opening/closing device 33A exceeds the resistance threshold value Th11 and the first opening/closing device 33A is in a degraded state, or when it is determined that the resistance value R2 of the fuse F exceeds the resistance threshold Th12 and the fuse F is in a degraded state.

With this configuration, performing anomaly response processing facilitates taking action that is based on which of the first opening/closing device 33A and the fuse F has degraded.

### Other Embodiments of Disclosure

The embodiments disclosed herein should be considered exemplary in all respects and not restrictive.

Different from the first embodiment, the voltage detection unit need only be connected at a place that can be regarded as having the same potential as the end-to-end potential of the first opening/closing device.

Different from the first embodiment, the notification function unit may be constituted as a display unit such as a lamp or a display device and may be configured to perform notification through display. The notification function unit may also be constituted by an audio device such as a speaker and may be configured to perform notification through audio.

Different from the first embodiment, the resistance value calculation unit, the degradation detection unit, and the notification function unit may each be constituted as individual information processing devices (individual microcomputers, etc.).

Different from the first embodiment, the control unit and the control device may be constituted as one microcomputer.

Different from the first embodiment, the degradation determination processing may be executed after determining that the rate of rise of the current on the power path is less than or equal to a certain value. For example, the following equation 1 derives an amount of change Ki of the current on the power path per unit time.

$$Ki = \vert A 1 - A 2 \vert / Δ T \qquad ( 1 )$$

Here, A1 is a current value A1 detected this time by the current detection unit, A2 is a current value A2 detected last time by the current detection unit, and ΔT is a period ΔT of time for which the current detection unit repeatedly detects the current value. The current value A2 can be stored in the RAM of the control unit, for example. The amount of change Ki is a value obtained by dividing the absolute value of the difference between the current value A1 and the current value A2 by the period ΔT. For example, when the state in which the amount of change Ki is smaller than the threshold value stored in the storage unit of the control unit continues for a predetermined period of time, it may be determined that the variability of the current flowing through the power line has settled, and, thereafter, the resistance value of the first opening/closing device may be calculated.

Different from the first embodiment, a configuration may also be adopted in which the third opening/closing device is not provided. In this case, a current rise occurs in which the value of current flowing through the power path rises sharply due to switching control being executed.

Different from the first embodiment, a configuration may even be adopted in which table data in which resistance values that correspond to current values and voltage values are determined is stored in the storage unit in advance, and resistance values that correspond to current values and voltage values are employed from the table data.

Different from the first embodiment, a configuration may also be adopted in which the potential difference of only one of the first opening/closing device and the fuse is detected, and the degraded state is determined for only the one of the first opening/closing device and the fuse.

The degraded state may be the potential difference itself, the resistance value, or a value derived by calculating the potential difference or resistance value as a variable.

### LIST OF REFERENCE NUMERALS

1 Degradation determination device
10 Power supply unit
11 Power path
15 Control unit
15A Resistance value calculation unit
15B Degradation detection unit
15C Notification function unit
15D Storage unit
17 Positive electrode-side power line (power path)
20 Negative electrode-side power line (power path)
33 System main relay
33A First opening/closing device
33B Second opening/closing device
33C Parallel opening/closing path (precharge circuit)
33D Resistor
33E Third opening/closing device
35 Load
37 Temperature detection unit
37A First temperature detection unit (temperature detection unit)
37B Second temperature detection unit (temperature detection unit)
38 Current detection unit
39 Potential detection unit
39A First potential detection unit (potential detection unit)
39B Second potential detection unit (potential detection unit)
100 Vehicle power supply system
A, A1, A2 Current value
C Control device
F Fuse
Ki Amount of change
R1, R2 Resistance value
Sd Degradation signal
Son On signal
Th11, Th12 Resistance threshold value
Th13 Current threshold value
Th14 Upper limit current threshold value
V1, V2 Potential difference
ΔT Period

1. A degradation determination device for determining whether an element provided on a power path, which is a path for transmitting power from a power supply unit to a load, is in a degraded state,
the power path having:
a positive electrode-side power line connected to a positive electrode-side terminal of the power supply unit; and
a negative electrode-side power line connected to a negative electrode-side terminal of the power supply unit,
the element being provided on the negative electrode-side power line,
the degradation determination device comprising:
a potential detection unit configured to detect a first potential at one end of the element and a second potential at an opposite end of the element; and
a control unit configured to determine whether the element is in a degraded state, based on a potential difference between the first potential and the second potential, and
the control unit determining whether the element is in a degraded state, based on the potential difference between the first potential and the second potential, after determining that a state in which a magnitude of a current value of the power path is within a range greater than or equal to a current threshold value and less than an upper limit current threshold value has continued for a predetermined period of time.

2. The degradation determination device according to claim 1,
wherein the element is a first element,
a second element different from the first element is provided on the positive electrode-side power line,
the degradation determination device further comprises a temperature detection unit configured to detect a temperature of each of the first element and the second element, and
the control unit determines whether the second element is in a degraded state, based on the potential difference and a temperature value detected by the temperature detection unit.

3. The degradation determination device according to claim 2,
wherein the first element and the second elements are each at least one of a relay and a fuse.

4. The degradation determination device according to claim 3,
wherein the first element and the second element are each a relay, and
a precharge circuit is connected to the power path so as to be in parallel with the first element.

5. The degradation determination device according to claim 1,
wherein the control unit performs anomaly response processing when it is determined that the element is in a degraded state.
